(19) United States
(12) Patent Application Publication
(10) Pub. No.: US 2026/0103790 A1
(43) Pub. Date: Apr. 16, 2026

(54) VIBRATION MITIGATION IN ION IMPLANTATION

(71) Applicant: Taiwan Semiconductor Manufacturing Company Limited, Hsin-Chu (TW)

(72) Inventor: Lung-Yin TANG, Keelung City (TW)

(21) Appl. No.: 18/916,810

(22) Filed: Oct. 16, 2024

(51) Int. Cl. C23C 14/54; C23C 14/48; H01L 21/265; H01L 21/66

(52) U.S. Cl. CPC C23C 14/54; C23C 14/48; H10P 30/204; H10P 30/21; H10P 74/238

(57) ABSTRACT

An apparatus is provided. The apparatus includes a disk configured to rotate during an ion implantation process. The apparatus includes a wafer support assembly coupled to the disk and configured to support one or more semiconductor wafers. The rotation of the disk causes the one or more semiconductor wafers to revolve along a path. The apparatus includes an ion implanter configured to emit an ion beam to a beam position along the path. The apparatus includes a vibration calibration device including a calibration base coupled to the disk and a first calibration unit coupled to the calibration base. The vibration calibration device is configured to move the first calibration unit from a first position to a second position to reduce a vibration associated with the apparatus.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an apparatus, in accordance with some embodiments.

FIG. 2 illustrates a diagram of a control system implemented using a vibration calibration device to mitigate vibration associated with an apparatus, in accordance with some embodiments.

FIG. 3A illustrates a vibration calibration device at a first time, in accordance with some embodiments.

FIG. 3B illustrates determination of a first set of target positions of a set of calibration units of a vibration calibration device, in accordance with some embodiments.

FIG. 3C illustrates a vibration calibration device at a second time, in accordance with some embodiments.

FIG. 4 is a flow diagram illustrating a method, in accordance with some embodiments.

FIG. 5 illustrates a recipe data structure for an ion implantation process, in accordance with some embodiments.

FIG. 6 is a flow diagram illustrating a method, in accordance with some embodiments.

FIG. 7 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

An ion implantation apparatus performs ion implantation for introducing dopants into one or more semiconductor wafers, such as for adjusting electrical properties of the semiconductor wafers. In some embodiments, the ion implantation apparatus (i) rotates a disk to cause the semiconductor wafers to revolve along a path and (ii) emits an ion beam to a beam position along the path. In some embodiments, the ion implantation apparatus vibrates due to at least one operational dynamics of the ion implantation apparatus, uneven load distribution imbalances of the ion implantation apparatus that result in vibration, ion beam interaction between the ion beam and a semiconductor wafer, etc.

In some embodiments, the ion implantation apparatus includes a vibration calibration device with a calibration base and a set of calibration units (e.g., a set of one or more calibration units) coupled to the calibration base. The vibration calibration device is configured to monitor one or more vibration metrics associated with the ion implantation apparatus and trigger a vibration calibration process in response to detecting a vibration metrics that meets (e.g., exceeds) a threshold. In some embodiments, in the vibration calibration process, the vibration calibration device (i) determines a set of target positions of the set of calibration units and (ii) moves one or more calibration units of the set of calibration units to one or more respective target positions of the set of target positions.

In some embodiments, moving the calibration units of the set of calibration units to respective target positions of the set of target positions mitigates (e.g., reduces, prevents and/or damps) vibration of the ion implantation apparatus. In some embodiments, the mitigation (and/or reduction and/or prevention) of vibration is due, at least in part, to the movement of the calibration units to the respective target positions reducing (e.g., minimizing and/or cancelling out) an imbalance associated with the ion implantation apparatus. In some embodiments, an imbalance of a rotating system may increase and/or exacerbate vibration of the rotating system. Thus, reducing (e.g., minimizing and/or cancelling out) an imbalance associated with the ion implantation apparatus provides for reduced vibration of the ion implantation apparatus, which, in turn, affords more desirable, predictable, etc. ion implantation into one or more semiconductor wafers to achieve more desirable, predictable, etc. electrical properties, performance, characteristics, etc. associated with the one or more semiconductor wafers and/or one or more semiconductor devices (e.g., transistors) formed on, in, and/or from the one or more semiconductor wafers.

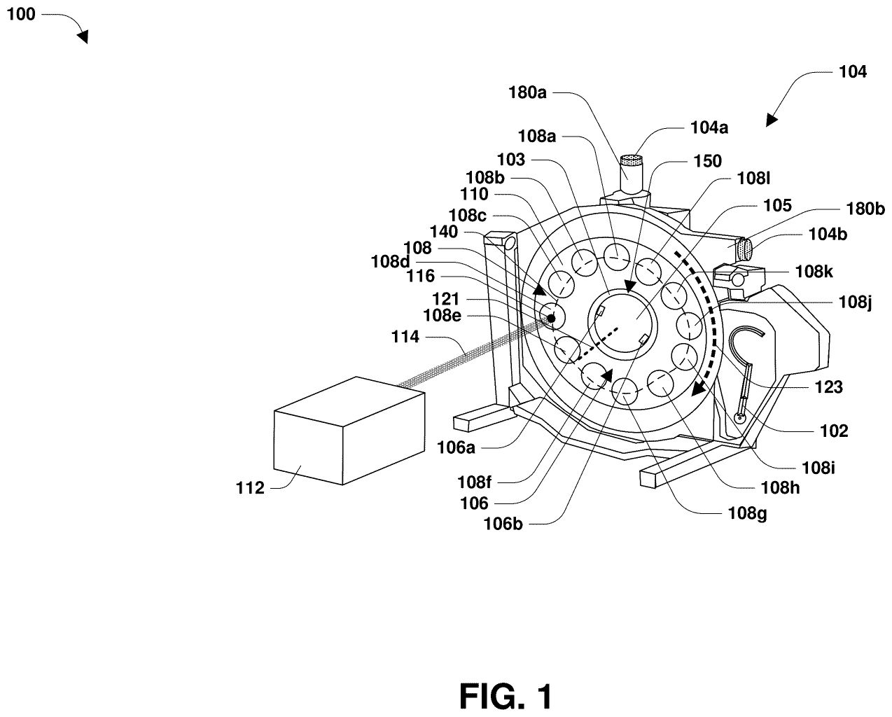

FIG. 1 illustrates an apparatus 100, in accordance with some embodiments. In some embodiments, the apparatus 100 comprises an ion implantation apparatus for introducing dopants into semiconductor wafers, such as for adjusting electrical properties of the semiconductor wafers. In some embodiments, the apparatus 100 comprises at least one of a disk 103, a wafer support assembly 110, an ion implanter 112, a vibration calibration device 150, an arm 102, or a set of vibration measurement devices 104 (e.g., a set of one or more vibration measurement devices). In some embodiments, the apparatus 100 is used to perform an ion implantation process on a set of semiconductor wafers 108 (e.g., a set of one or more semiconductor wafers).

In some embodiments, the wafer support assembly 110 is configured to support the set of semiconductor wafers 108. In some embodiments, the set of semiconductor wafers 108 comprises at least one of a semiconductor wafer 108a, a semiconductor wafer 108b, a semiconductor wafer 108c, a semiconductor wafer 108d, a semiconductor wafer 108e, a semiconductor wafer 108f, a semiconductor wafer 108g, a semiconductor wafer 108h, a semiconductor wafer 108i, a semiconductor wafer 108j, a semiconductor wafer 108k, or a semiconductor wafer 108l. Although twelve semiconductor wafers are illustrated in FIG. 1, any number of semiconductor wafers of the set of semiconductor wafers 108 is contemplated in the present disclosure. In some embodiments, one, some, or all of the set of semiconductor wafers 108 is transferred to and/or mounted on the wafer support assembly 110 using the arm 102. In some embodiments, the arm 102 comprises at least one of a wafer handling device, a robotic arm, etc. In some embodiments, the wafer support assembly 110 is coupled to the disk 103.

In some embodiments, the disk 103 is configured to rotate in a rotational direction 123 during the ion implantation process. In some embodiments, the disk 103 is rotated in the rotational direction 123 using a first driving mechanism (not shown), such as a motor configured to drive the disk 103, to rotate the disk 103 in the rotational direction 123 about a first axis of rotation 121. In some embodiments, the rotation of the disk 103 in the rotational direction 123 causes the set of semiconductor wafers 108 to revolve along a path 140 (shown with a dashed-line in FIG. 1).

In some embodiments, the ion implanter 112 is configured to emit an ion beam 114 (e.g., a pencil beam and/or other type of ion beam) to a beam position 116 along the path 140 during the ion implantation process. In some embodiments, during the ion implantation process, the set of semiconductor wafers 108 revolve along the path 140 such that the ion beam 114 impinges upon each semiconductor wafer of one, some or all of the set of semiconductor wafers 108 such that dopants are introduced into the semiconductor wafer. In some embodiments, the beam position 116 of the ion beam 114 remains fixed throughout the ion implantation process. Embodiments are contemplated in which the beam position 116 changes throughout the ion implantation process.

In some embodiments, the apparatus 100 vibrates due to at least one of (i) operational dynamics of the apparatus 100 throughout the ion implantation process, such as at least one of variations in rotation speed of the disk 103, uneven load distribution (e.g., uneven wafer placement across the wafer support assembly 110), thermal expansion associated with ion implantation, etc., (ii) mechanical imperfections and/or imbalances of the apparatus 100 that result in vibration at high rotational speeds, or (iii) ion beam interaction between the ion beam 114 and at least one of the disk 103, the wafer support assembly 110, or the set of semiconductor wafers 108.

In some embodiments, the vibration calibration device 150 is used to mitigate (e.g., reduce, prevent and/or damp) vibration associated with the apparatus 100. In some embodiments, the vibration calibration device 150 comprises at least one of a calibration base 105 or a set of calibration units 106 (e.g., a set of one or more calibration units) coupled to the calibration base 105. In some embodiments, the calibration base 105 is coupled to (e.g., affixed to) the disk 103, such as via at least one of one or more screws, an adhesive, etc. In some embodiments, the vibration calibration device 150 adjusts one or more positions of one, some or all calibration units of the set of calibration units 106 to mitigate (e.g., reduce, prevent and/or damp) vibration associated with the apparatus 100.

In some embodiments, the set of calibration units 106 comprises at least one of a first calibration unit 106a or a second calibration unit 106b. Although two calibration units are illustrated in FIG. 1, any number of calibration units of the set of calibration units 106 is contemplated in the present disclosure. In some embodiments, adjusting positions of the set of calibration units 106 relative to the calibration base 105 provides for increased accuracy of vibration control associated with the apparatus 100. In some embodiments, each calibration unit of one, some or all of the set of calibration units 106 at least one of (i) comprises at least one of a weight, a block, etc., (ii) is coupled (e.g., moveably coupled) to the calibration base 105, or (iii) engages with a rail (not shown) defined by the calibration base 105. In some embodiments, the rail extends along an edge and/or circumference of the calibration base 105. In some embodiments, a calibration unit (e.g., at least one of the first calibration unit 106a, the second calibration unit 106b, etc.) of the set of calibration units 106 engages with at least one of the rail or the calibration base 105 using a clamping mechanism (not shown). In some embodiments, the clamping mechanism transitions between a tightened state in which the clamping mechanism supports the calibration unit in a location (e.g., a fixed location along the rail defined by the calibration base 105) and a loosened state in which the clamping mechanism allows the calibration unit to be moved along the rail from the location to a different location.

In some embodiments, the set of vibration measurement devices 104 comprises at least one of a first vibration measurement device 104a or a second vibration measurement device 104b. Although two vibration measurement devices are illustrated in FIG. 1, any number of vibration measurement devices of the set of vibration measurement devices 104 is contemplated in the present disclosure. In some embodiments, each vibration measurement device of one, some or all of the set of vibration measurement devices 104 at least one of (i) is coupled to and/or in contact with a portion of the apparatus 100, or (ii) comprises a sensor (e.g., an accelerometer, a motion sensor, a proximity sensor, etc.) to measure vibration metrics associated with the portion of the apparatus 100 (e.g., by converting mechanical motion of the portion and/or the sensor into an electrical signal indicative of a vibration metric).

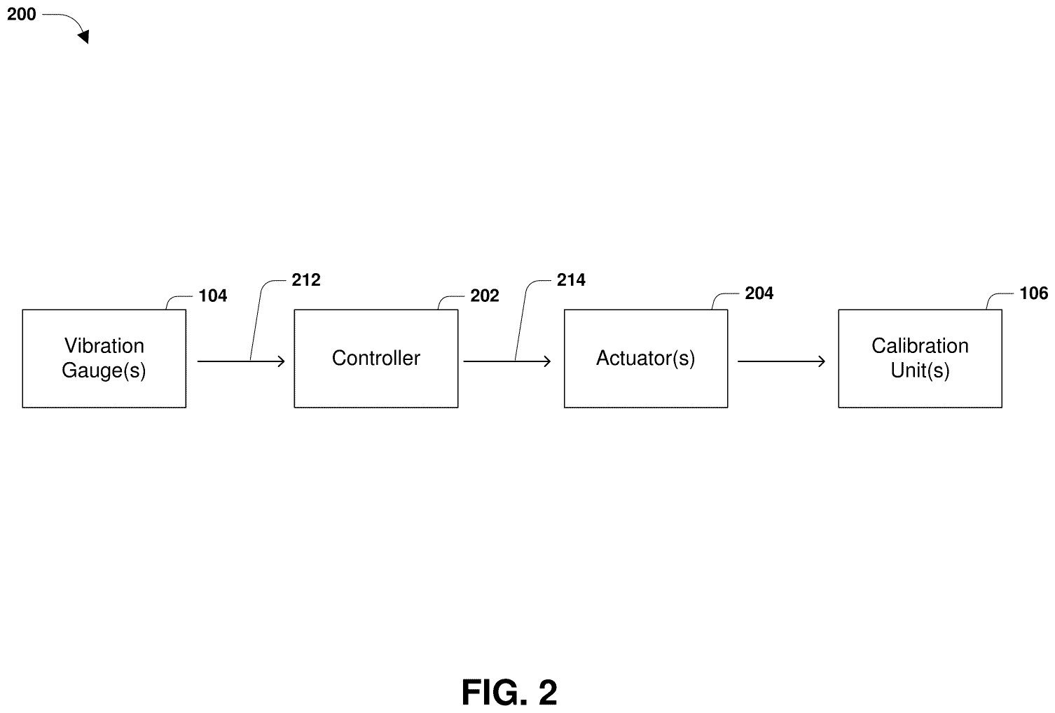

FIG. 2 illustrates a control system 200 implemented using the vibration calibration device 150 to mitigate vibration associated with the apparatus 100, in accordance with some embodiments. In some embodiments, the vibration calibration device 150 comprises at least one of a controller 202 or a set of actuators 204 (e.g., a set of one or more actuators). In some embodiments, the controller 202 receives one or more vibration metric signals 212 from the set of vibration measurement devices 104. In some embodiments, each vibration metric signal of one, some, or all of the one or more vibration metric signals 212 is indicative of one or more vibration metrics determined using a vibration measurement device of the set of vibration measurement devices 104. In some embodiments, the one or more vibration metric signals 212 comprises at least one of (i) a first vibration metric signal indicative of a first set of vibration metrics (e.g., a first set of one or more vibration metrics) determined using the first vibration measurement device 104a, (ii) a second vibration metric signal indicative of a second set of vibration metrics (e.g., a second set of one or more vibration metrics) determined using the second vibration measurement device 104b, or (iii) one or more other vibration metric signals indicative of one or more other sets of vibration metrics determined using one or more other vibration measurement devices of the set of vibration measurement devices 104.

In some embodiments, the one or more vibration metric signals 212 are indicative of and/or usable to determine at least one of a vibration frequency, an angular velocity, a vibration force, an amplitude, an amplitude intensity, an acceleration, etc. associated with vibration of the apparatus 100. In some embodiments, the first vibration metric signal is indicative of and/or usable to determine at least one of a vibration frequency, an angular velocity, a vibration force, an amplitude, an amplitude intensity, an acceleration, etc. associated with vibration of a portion 180a (shown in FIG. 1) of the apparatus 100. In some embodiments, the portion 180a corresponds to at least a portion of a first body, chassis, and/or mechanical component of the apparatus 100. In some embodiments, the second vibration metric signal is indicative of and/or usable to determine at least one of a vibration frequency, an angular velocity, a vibration force, an amplitude, an amplitude intensity, an acceleration, etc. associated with vibration of a portion 180b (shown in FIG. 1) of the apparatus 100. In some embodiments, the portion 180b corresponds to at least a portion of a second body, chassis, and/or mechanical component of the apparatus 100.

In some embodiments, the controller 202 controls one or more positions of one, some or all of the set of calibration units 106 based upon the one or more vibration metric signals 212. In some embodiments, the controller 202 determines a vibration profile associated with the apparatus 100 based upon the one or more vibration metric signals 212. In some embodiments, the vibration profile is indicative of at least one of (i) a set of apparatus vibration metrics indicative of at least one of a first frequency, a first angular velocity, a first vibration force, a first amplitude, a first amplitude intensity, a first acceleration, etc. associated with vibration of the apparatus 100 (e.g., metrics indicated by the one or more vibration metric signals 212 are combined to determine the set of apparatus vibration metrics), (ii) a first set of apparatus portion vibration metrics indicative of at least one of a second frequency, a second angular velocity, a second vibration force, a second amplitude, a second amplitude intensity, a second acceleration, etc. associated with vibration of the portion 180a (shown in FIG. 1) of the apparatus 100 (e.g., the first set of apparatus portion vibration metrics is determined based upon the first vibration metric signal of the one or more vibration metric signals 212), or (iii) a second set of apparatus portion vibration metrics indicative of at least one of a third frequency, a third angular velocity, a third vibration force, a third amplitude, a third amplitude intensity, a third acceleration, etc. associated with vibration of the portion 180b (shown in FIG. 1) of the apparatus 100 (e.g., the second set of apparatus portion vibration metrics is determined based upon the second vibration metric signal of the one or more vibration metric signals 212).

In some embodiments, the controller 202 controls one or more positions of one, some or all of the set of calibration units 106 based upon the vibration profile. In some embodiments, the controller 202 controls one or more positions of one, some, or all of the set of calibration units 106 using the set of actuators 204. In some embodiments, each actuator of one, some or all of the set of actuators 204 at least one of (i) comprises at least one of a motor (e.g., an electric motor or other type of motor), a hydraulic and/or pneumatic cylinder, a solenoid, a stepper motor, a servo actuator, etc. that controls a position of a calibration unit of the set of calibration units 106, (ii) is coupled to the calibration unit, or (iii) exerts a moving force to the calibration unit to move the calibration unit (along the rail defined by the calibration base 105, for example). In some embodiments, prior to exerting the moving force to the calibration unit, the clamping mechanism transitions from the tightened state to the loosened state to allow the calibration unit to be moved from a first location to a second location (e.g., the calibration unit is moved along the rail defined by the calibration base 105 from the first location to the second location). In some embodiments, the clamping mechanism transitions from the tightened state to the loosened state in response to the controller 202 transmitting an instruction, to the clamping mechanism, to transition from the tightened state to the loosened state. In some embodiments, in response to moving the calibration unit from the first location to the second location, the clamping mechanism transitions from the loosened state to the tightened state to support the calibration unit in the second location. In some embodiments, the clamping mechanism transitions from the loosened state to the tightened state in response to the controller 202 transmitting an instruction, to the clamping mechanism, to transition from the loosened state to the tightened state. In some embodiments, the set of actuators 204 comprises at least one of (i) a first actuator (e.g., a first motor, a first hydraulic and/or pneumatic cylinder, a first solenoid, a first stepper motor, a first servo actuator, etc.) configured to move and/or control a position of the first calibration unit 106a, (ii) a second actuator (e.g., a second motor, a second hydraulic and/or pneumatic cylinder, a second solenoid, a second stepper motor, a second servo actuator, etc.) configured to move and/or control a position of the second calibration unit 106b, or (iii) one or more other actuators configured to move and/or control one or more positions of one or more other calibration units of the set of calibration units 106.

In some embodiments, the controller 202 transmits one or more control signals 214 to the set of actuators 204. In some embodiments, the controller 202 generates the one or more control signals 214 based upon the vibration profile associated with the apparatus 100. In some embodiments, each control signal of one, some, or all of the one or more control signals 214 is indicative of a target position of a corresponding calibration unit of the set of calibration units 106. In some embodiments, the one or more control signals 214 are indicative of a set of target positions (e.g., a set of one or more target positions) associated with the set of calibration units 106. In some embodiments, the controller 202 determines the set of target positions based upon the vibration profile associated with the apparatus 100. In some embodiments, the set of target positions comprises at least one of (i) a first target position of the first calibration unit 106a, (ii) a second target position of the second calibration unit 106b, or (iii) one or more other target positions of one or more other calibration units of the set of calibration units 106. In some embodiments, the one or more control signals 214 comprise at least one of (i) a first control signal indicative of the first target position of the first calibration unit 106a, (ii) a second control signal indicative of the second target position of the second calibration unit 106b, or (iii) one or more other control signals indicative of the one or more other target positions of the one or more other calibration units of the set of calibration units 106.

In some embodiments, each actuator of one, some or all of the set of actuators 204 controls a position of a corresponding calibration unit (e.g., at least one of the first calibration unit 106a, the second calibration unit 106b, etc.) of the set of calibration units 106 based upon a control signal (e.g., at least one of the first control signal, the second control signal, etc.) of the one or more control signals 214. In some embodiments, the actuator controls the position of the corresponding calibration unit based upon a target position indicated by the control signal. In some embodiments, in response to detecting a change to the target position indicated by the control signal, the actuator moves the corresponding calibration unit from a prior position to an updated position.

In some embodiments, the first actuator of the set of actuators 204 controls a position of the first calibration unit 106a based upon the first control signal, such as based upon the first target position indicated by the first control signal. In some embodiments, in response to detecting a change to the first target position indicated by the first control signal, the first actuator moves the first calibration unit 106a from a prior position to an updated position. In some embodiments, the second actuator of the set of actuators 204 controls a position of the second calibration unit 106b based upon the second control signal, such as based upon the second target position indicated by the second control signal. In some embodiments, in response to detecting a change to the second target position indicated by the second control signal, the second actuator moves the second calibration unit 106b from a prior position to an updated position.

In some embodiments, the controller 202 updates one or more values of one, some or all target positions of the set of target positions (based upon the vibration profile, for example) during a vibration calibration process. In some embodiments, the controller 202 triggers the vibration calibration process in response to a vibration metric associated with the apparatus 100 meeting (e.g., exceeding) a predefined vibration metric threshold. In some embodiments, the predefined vibration metric threshold comprises at least one of a threshold frequency, a threshold angular velocity, a threshold vibration force, a threshold amplitude, a threshold amplitude intensity, a threshold acceleration, or other vibration metric threshold. In some embodiments, the predefined vibration metric threshold is adjustable. In some embodiments, the predefined vibration metric threshold is dependent upon at least one of (i) one or more characteristics associated with the set of semiconductor wafers 108 (e.g., a wafer type of a semiconductor wafer, a material of the semiconductor wafer, a thickness of the semiconductor wafer, etc.), (ii) one or more characteristics of the ion implantation process (e.g., a precision requirement of the ion implantation process, an energy level associated with the ion implantation process, a dopant concentration associated with the ion implantation process, etc.), or (iii) one or more other characteristics and/or parameters associated with the apparatus 100. In some embodiments, the predefined vibration metric threshold is determined based upon a recipe associated with the ion implantation process.

In some embodiments, the controller 202 determines (e.g., continuously, discontinuously, and/or periodically determines and/or updates) a vibration metric (e.g., a vibration metric of the vibration profile or determined based upon the vibration profile). In some embodiments, the controller 202 monitors (e.g., continuously, discontinuously, and/or periodically monitors) the vibration metric (by comparing the vibration metric and/or updated values of the vibration metric with the predefined vibration metric threshold, for example). In some embodiments, the controller 202 triggers the vibration calibration process in response to detecting (via the monitoring, for example) the vibration metric meeting the predefined vibration metric threshold. In some embodiments, the vibration metric comprises (or is determined and/or updated based upon) at least one of the first frequency, the first angular velocity, the first vibration force, the first amplitude, the first amplitude intensity, the first acceleration, other metric of the set of apparatus vibration metrics, the second frequency, the second angular velocity, the second vibration force, the second amplitude, the second amplitude intensity, the second acceleration, other metric of the first set of apparatus portion vibration metrics, the third frequency, the third angular velocity, the third vibration force, the third amplitude, the third amplitude intensity, the third acceleration, other metric of the second set of apparatus portion vibration metrics, or other suitable vibration metric.

In some embodiments, in response to triggering the vibration calibration process, the controller 202 performs a calibration unit repositioning process. In some embodiments, in the calibration unit repositioning process, the controller 202 at least one of (i) determines one or more updated target position values based upon the vibration profile, (ii) updates one or more values of one, some or all target positions of the set of target positions based upon the one or more updated target position values, or (iii) updates one or more first control signals (e.g., one, some or all control signals of the one or more control signals 214) to be indicative of the one or more updated target position values, respectively. In some embodiments, in response to updating the one or more first control signals to be indicative of the one or more updated target position values, respectively, one, some or all of the set of actuators 204 are triggered to move one, some or all of the set of calibration units 106 to one or more updated target positions identified by the one or more updated target position values.

In some embodiments, in response to performing the calibration unit repositioning process, the controller 202 at least one of (i) determines an updated vibration metric based upon at least one of one or more updated and/or current values indicated by the vibration profile and/or the one or more vibration metric signals 212, or (ii) compares the updated vibration metric with the threshold predefined vibration metric threshold.

In some embodiments, in response to determining that the updated vibration metric does not meet (e.g., does not exceed) the threshold predefined vibration metric threshold, the controller 202 at least one of (i) triggers completion of the vibration calibration process, (ii) determines (e.g., continuously, discontinuously, and/or periodically determines and/or updates) one or more vibration metrics associated with the apparatus 100 based upon the vibration profile (e.g., based upon updated and/or current vibration metrics indicated by the vibration profile and/or the one or more vibration metric signals 212), or (iii) monitors (e.g., continuously, discontinuously, and/or periodically monitors) the one or more vibration metrics (by comparing the one or more vibration metrics and/or updated values of the one or more vibration metrics with the predefined vibration metric threshold, for example).

In some embodiments, in response to determining that the updated vibration metric meets (e.g., exceeds) the threshold predefined vibration metric threshold, the controller 202 at least one of (i) triggers a second calibration unit repositioning process, or (ii) performs one or more calibration unit repositioning process iterations (e.g., at least one of the second calibration unit repositioning process, a third calibration unit repositioning process, etc.) using one or more of the techniques provided herein with respect to the calibration unit repositioning process. In some embodiments, the controller 202 ceases performing the one or more calibration unit repositioning process iterations in response to determining that vibration associated with the apparatus 100 is reduced to less than a threshold vibration. In some embodiments, the controller 202 ceases performing the one or more calibration unit repositioning process iterations in response to determining that an updated vibration metric determined after a unit repositioning process iteration of the one or more calibration unit repositioning process iterations does not meet (e.g., does not exceed) the predefined vibration metric threshold (e.g., the controller 202 performs one or more iterations of calibration unit repositioning process until the determination that the updated vibration metric does not meet the predefined vibration metric threshold).

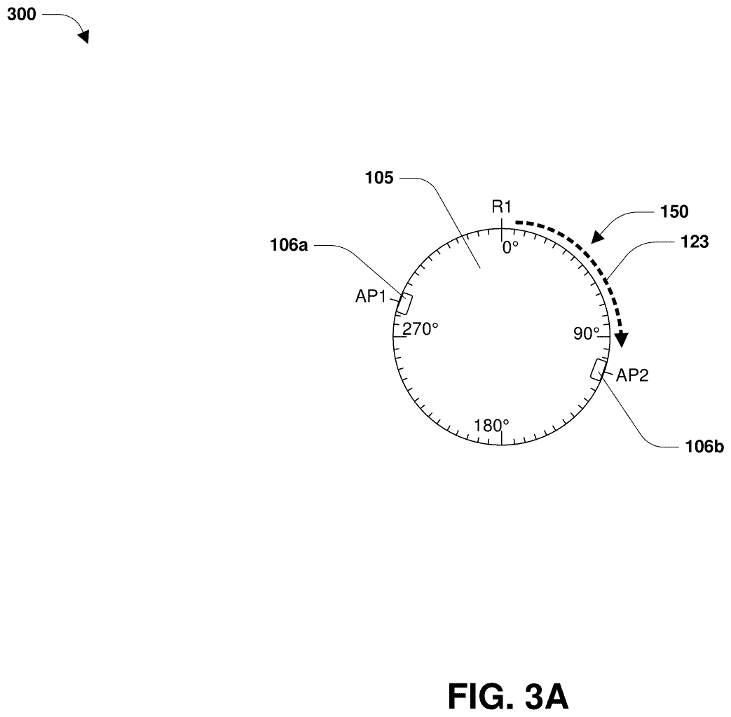

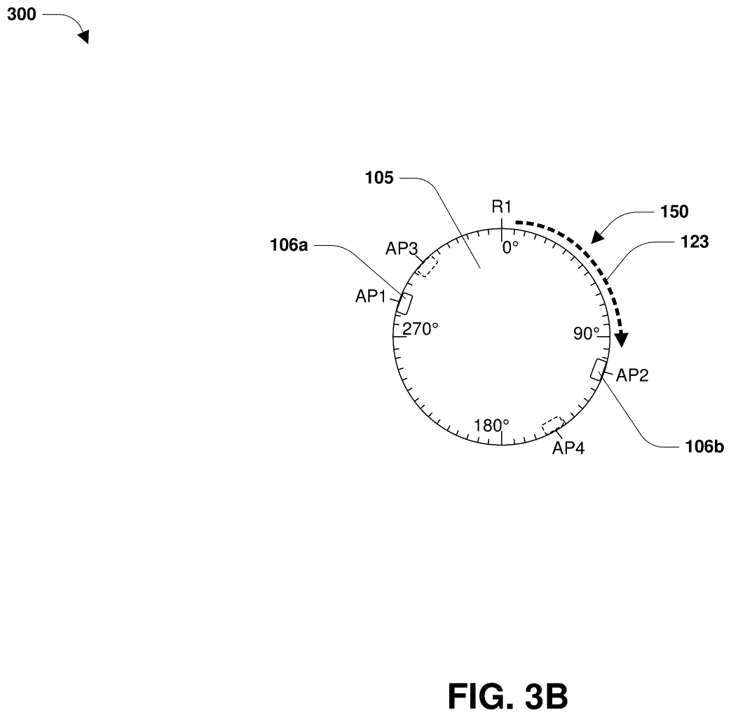

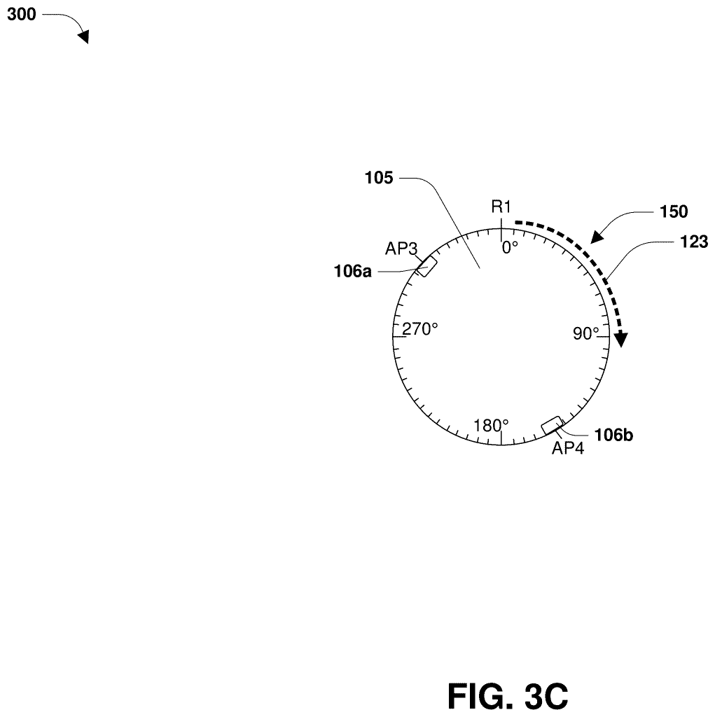

FIGS. 3A-3C illustrate a scenario 300 of the vibration calibration device 150 performing at least some of the vibration calibration process, in accordance with some embodiments. In some embodiments, the scenario 300 and/or the vibration calibration process, is associated with use of the vibration calibration device 150 to mitigate (e.g., reduce, prevent and/or damp) vibration associated with the apparatus 100 during the ion implantation process, thereby improving stability and/or performance of the ion implantation process.

FIG. 3A illustrates the vibration calibration device 150 at a first time, in accordance with some embodiments. In some embodiments, the first time is during the ion implantation process. In some embodiments, at the first time, at least one of (i) the disk 103 is rotating, causing the set of semiconductor wafers 108 to revolve along the path 140 (shown in FIG. 1) or (ii) the ion beam 114 is being emitted to the beam position 116 along the path 140 to introduce dopants to one, some or all of the set of semiconductor wafers 108. In some embodiments, at the first time, at least one of (i) the first calibration unit 106a is at a first position, or (ii) the second calibration unit 106b is at a second position. In some embodiments, the first position corresponds to a first angular position AP1 relative to a reference position R1. In some embodiments, the reference position R1 corresponds to a starting reference position of 0 degrees relative to a reference circle. In some embodiments, the first position is indicated by a first angular difference (e.g., 295 degrees) between the first angular position AP1 and the reference position R1. In some embodiments, the second position corresponds to a second angular position AP2 relative to the reference position R1. In some embodiments, the second position is indicated by a second angular difference (e.g., 115 degrees) between the second angular position AP2 and the reference position R1.

In some embodiments, at least one of the calibration base 105 or the reference position R1 of the calibration base 105 remains stationary (e.g., fixed in place during rotation, anchored to a fixed position, etc.) relative to the disk 103 as the disk 103 rotates in the rotational direction 123. In some embodiments, the disk 103 rotates in the rotational direction 123 (and/or causes the set of semiconductor wafers 108 to revolve along the path 140) independently of the fixed calibration base 105. Embodiments are contemplated in which the calibration base 105 rotates during the ion implantation process (e.g., at least one of the calibration base 105 or the reference position R1 of the calibration base 105 rotates in the rotational direction 123 as the disk 103 rotates in the rotational direction 123). Embodiments are contemplated in which the disk 103 is rotated in a different direction (e.g., a rotational direction opposite to the rotational direction 123).

In some embodiments, the controller 202 triggers the vibration calibration process in response to determining that a vibration metric (e.g., a vibration metric determined based upon one or more vibration metric values, associated with the first time, indicated by the vibration profile and/or the one or more vibration metric signals 212) associated with the apparatus 100 meets the predefined vibration metric threshold. In some embodiments, in response to triggering the vibration calibration process, the controller 202 performs a calibration unit repositioning process in which the controller 202 (i) determines a first set of target positions (e.g., a first set of one or more target positions) associated with the set of calibration units 106, (ii) generates the one or more control signals 214 to be indicative of the first set of target positions, or (iii) instructs one, some or all of the set of actuators 204 to move one, some or all of the set of calibration units 106 to one or more respective target positions of the first set of target positions.

FIG. 3B illustrates determination, by the controller 202 (shown in FIG. 2), of the first set of target positions, in accordance with some embodiments. In some embodiments, the first set of target positions comprises at least one of a first target position of the first calibration unit 106a, a second target position of the second calibration unit 106b, or one or more other target positions of one or more other calibration units of the set of calibration units 106. In some embodiments, the first target position corresponds to a third angular position AP3 relative to the reference position R1. In some embodiments, the first target position is indicated by a third angular difference (e.g., 315 degrees) between the third angular position AP3 and the reference position R1. In some embodiments, the second target position corresponds to a fourth angular position AP4 relative to the reference position R1. In some embodiments, the second target position is indicated by a second angular difference (e.g., 150 degrees) between the fourth angular position AP4 and the reference position R1.

In some embodiments, the controller 202 determines a vibration frequency f associated with vibration of the apparatus 100 based upon the vibration profile and/or the one or more vibration metric signals 212. In some embodiments, the controller 202 determines the vibration frequency f based upon (e.g., to be equal to about) R [rpm]/60 [s] [hertz]. In some embodiments, the controller 202 determines a tool initial angular velocity ω0 associated with vibration of the apparatus 100. In some embodiments, the tool initial angular velocity ω0 is determined based upon a first pre-defined angular velocity value associated with at least one of a vibration measurement device of the set of vibration measurement devices 104 or the apparatus 100. In some embodiments, the first pre-defined angular velocity value is stored in a memory unit of at least one of a vibration measurement device of the set of vibration measurement devices 104, a component of the apparatus 100, the controller 202, etc. In some embodiments, the first pre-defined angular velocity value is set by a manufacturer of at least one of a vibration measurement device of the set of vibration measurement devices 104 or one or more components of the apparatus 100. In some embodiments, the first pre-defined angular velocity value is indicated by a datasheet associated with at least one of a vibration measurement device of the set of vibration measurement devices 104 or one or more components of the apparatus 100. In some embodiments, the tool initial angular velocity ω0 changes over time. In some embodiments, the tool initial angular velocity ω0 is determined based upon the first pre-defined angular velocity value and a current time. In some embodiments, the tool initial angular velocity ω0 is determined using a vibration measurement device of the set of vibration measurement devices 104. In some embodiments, the tool initial angular velocity ω0 is determined based upon the first pre-defined angular velocity value and a vibration metric determined using a vibration measurement device of the set of vibration measurement devices 104.

In some embodiments, the controller 202 determines an angular velocity ω1. In some embodiments, the angular velocity ω1 is determined based upon a second pre-defined angular velocity value associated with at least one of a vibration measurement device of the set of vibration measurement devices 104 or the apparatus 100. In some embodiments, the second pre-defined angular velocity value is stored in a memory unit of at least one of a vibration measurement device of the set of vibration measurement devices 104, a component of the apparatus 100, the controller 202, etc. In some embodiments, the second pre-defined angular velocity value is set by a manufacturer of at least one of a vibration measurement device of the set of vibration measurement devices 104 or one or more components of the apparatus 100. In some embodiments, the second pre-defined angular velocity value is indicated by a datasheet associated with at least one of a vibration measurement device of the set of vibration measurement devices 104 or one or more components of the apparatus 100. In some embodiments, the angular velocity ω1 changes over time. In some embodiments, the angular velocity ω1 is determined based upon the second pre-defined angular velocity value and a current time. In some embodiments, the angular velocity ω1 is determined using a vibration measurement device of the set of vibration measurement devices 104. In some embodiments, the angular velocity ω1 is determined based upon the second pre-defined angular velocity value and a vibration metric determined using a vibration measurement device of the set of vibration measurement devices 104.

In some embodiments, the controller 202 determines at least one of the tool initial angular velocity ω0 or the angular velocity ω1 based upon (e.g., to be equal to about) 2×π×f[1/s]. In some embodiments, the controller 202 determines a vibration force F associated with vibration of the apparatus 100 based upon the vibration profile and/or the one or more vibration metric signals 212. In some embodiments, the vibration force F corresponds to a vibration force generated by a rotating mass, such as by rotation of at least one of the disk 103, the wafer support assembly 110, or the set of semiconductor wafers 108. In some embodiments, the vibration force F is associated with a vibration of at least a portion of a housing structure of the apparatus 100. In some embodiments, the housing structure comprises at least one of (i) the first body, chassis and/or mechanical component to which the first vibration measurement device 104a is connected, or (ii) the second body, chassis and/or mechanical component to which the second vibration measurement device 104b is connected.

In some embodiments, the vibration force F is defined as F=m×r×ω² [N], wherein at least one of (i) m corresponds to a mass of the set of calibration units 106, (ii) r corresponds to an amplitude associated the vibration, or (iii) angular velocity value w is determined by the controller 202. In some embodiments, the controller 202 determines the vibration force F based upon the vibration profile and/or the one or more vibration metric signals 212. In some embodiments, the controller 202 determines the mass m based upon a predefined value. In some embodiments, the controller 202 determines the amplitude r based upon the vibration profile and/or the one or more vibration metric signals 212. In some embodiments, in response to determining values of at least one of the vibration force F, the amplitude r, or the mass m, the controller 202 uses the values to determine the angular velocity value ω based upon

$$\sqrt{\frac{F}{m \times r}}$$

(e.g., the angular velocity value w is determined to be equal to about

$$\frac{F}{m \times g} ,$$

In some embodiments, the controller 202 determines one or more target positions of the first set of target positions based upon the angular velocity value ω determined based upon the values. In some embodiments, the controller 202 determines an amplitude intensity T associated with vibration of the apparatus 100 based upon the vibration profile and/or the one or more vibration metric signals 212. In some embodiments, the controller 202 determines the amplitude intensity T based upon (e.g., to be equal to about)

$$\sqrt{\frac{F}{m \times r}} ) .$$

wherein g corresponds to an acceleration associated with gravity.

In some embodiments, the controller 202 determines the first set of target positions based upon at least one of the angular velocity value ω, vibration frequency f, the tool initial angular velocity ω0, the angular velocity ω1, the angular velocity value ω, the vibration force F, the mass m, the amplitude r, the amplitude intensity T, or one or more other metrics indicated by and/or determined based upon the vibration profile associated with the apparatus 100. In some embodiments, the controller 202 at least one of (i) determines a first target position offset angle θ1 based upon (e.g., to be equal to about) 2.5×T×(A3×A8−A4×A7)/(A5×A8−A6×A7) or (ii) determines a second target position angle O2 based upon (e.g., to be equal to about) 2.5×T×(A3×A6−A4×A5)/(A7×A6−A8×A5). In some embodiments, at least one of (i) A3=COS(π*(ω0+ω1)/180), (ii) A4=SIN(π*(ω0+ω1)/180), (iii) A5=COS(π*(α+90)/180), (iv) A6=SIN(π*(α+90)/180), (v) A7=COS(π*(β+90)/180), (vi) A8=SIN(π*(α+90)/180), (vii) a corresponds to a calibration unit angle (e.g., the first angular position AP1) associated with a calibration unit (e.g., at least one of the first calibration unit 106a, the second calibration unit 106b, etc.) of the set of calibration units 106, or (viii) β corresponds to a calibration unit angle associated with the calibration unit (e.g., at least one of the first calibration unit 106a, the second calibration unit 106b, etc.) of the set of calibration units 106. In some embodiments, calibration unit angle α corresponds to a prior target position estimate of the calibration unit. In some embodiments, the calibration unit is moved to a position corresponding to the prior target position estimate in response to the controller 202 determining the prior target position estimate. In some embodiments, calibration unit angle β corresponds to a subsequent target position estimate of the calibration unit. In some embodiments, the calibration unit is moved from the position corresponding to the prior target position estimate to a different position corresponding to the subsequent target position estimate of the calibration unit in response to the controller 202 at least one of (i) determining one or more updated values (e.g., an updated vibration force value corresponding to an updated value of the vibration force F, an updated amplitude value corresponding to an updated value of the amplitude r, etc.) while the calibration unit is at the position corresponding to the prior target position estimate, or (ii) determining that the one or more updated values (and/or one or more vibration metrics derived from the one or more updated values) meet one or more thresholds (e.g., the predefined vibration metric threshold). In some embodiments, the controller 202 determines the subsequent target position estimate of the calibration unit based upon the one or more updated values. In some embodiments, the controller 202 determines a target position (of the first set of target positions) associated with the calibration unit based upon at least one of the prior target position estimate or the subsequent target position estimate. In some embodiments, the subsequent target position estimate corresponds to the first position (e.g., AP1) of the first calibration unit 106a or the second position (e.g., AP2) of the second calibration unit 106b.

In some embodiments, the controller 202 determines the first target position (e.g., AP3) based upon the first target position offset angle O1. In some embodiments, the controller 202 applies the first target position offset angle O1 to the first position (e.g., AP1) of the first calibration unit 106a to determine the first target position (e.g., AP3). In some embodiments, the controller 202 adds the first target position offset angle O1 to the first position (e.g., AP1) or subtracts the first target position offset angle O1 from the first position (e.g., AP1) to determine the first target position (e.g., AP3). In some embodiments, the controller 202 transmits a signal comprising at least one of an indication of the first target position offset angle O1 or the first target position (e.g., AP3) to the first actuator associated with the first calibration unit 106a. In some embodiments, in response to receiving the signal, the first actuator moves the first calibration unit 106a from the first position (e.g., AP1) to the first target position (e.g., AP3). In some embodiments, the first calibration unit 106a is moved along the rail from the first position (e.g., AP1) to the first target position (e.g., AP3).

In some embodiments, the controller 202 determines the second target position (e.g., AP4) based upon the second target position offset angle O2. In some embodiments, the controller 202 applies the second target position offset angle O2 to the second position (e.g., AP2) of the second calibration unit 106b to determine the second target position (e.g., AP4). In some embodiments, the controller 202 adds the second target position offset angle O2 to the second position (e.g., AP2) or subtracts the second target position offset angle O2 from the second position (e.g., AP2) to determine the second target position (e.g., AP4). In some embodiments, the controller 202 transmits a signal comprising at least one of an indication of the second target position offset angle O2 or the second target position (e.g., AP4) to the second actuator associated with the second calibration unit 106b. In some embodiments, in response to receiving the signal, the second actuator moves the second calibration unit 106b from the second position (e.g., AP2) to the second target position (e.g., AP4). In some embodiments, the second calibration unit 106b is moved along the rail from the second position (e.g., AP2) to the second target position (e.g., AP4).

FIG. 3C illustrates the vibration calibration device 150 at a second time subsequent to moving calibration units of the set of calibration units 106 to respective target positions of the set of target positions, in accordance with some embodiments. In some embodiments, the second time is during the ion implantation process. In some embodiments, at the second time, at least one of (i) the disk 103 is rotating, causing the set of semiconductor wafers 108 to revolve along the path 140 (shown in FIG. 1) or (ii) the ion beam 114 is being emitted to the beam position 116 along the path 140 to introduce dopants to one, some or all of the set of semiconductor wafers 108. In some embodiments, at the second time, at least one of (i) the first calibration unit 106a is at the first target position (e.g., AP3), or (ii) the second calibration unit 106b is at the second target position (e.g., AP4).

In some embodiments, moving the calibration units of the set of calibration units 106 to respective target positions of the set of target positions mitigates (e.g., reduces, prevents and/or damps) vibration of the apparatus 100. In some embodiments, the mitigation (and/or reduction and/or prevention) of vibration is due, at least in part, to the movement of the calibration units to the respective target positions reducing (e.g., minimizing and/or cancelling out) an imbalance associated with the apparatus 100. In some embodiments, an imbalance of a rotating system may increase and/or exacerbate vibration of the rotating system. Thus, reducing (e.g., minimizing and/or cancelling out) an imbalance associated with the apparatus 100 provides for reduced vibration of the apparatus 100.

In some embodiments, reduced vibration achieved using the vibration calibration device 150 provides for at least one of (i) improved uniformity of doping across target regions of the set of semiconductor wafers 108, (ii) reduced wafer damage that would otherwise result from non-mitigated vibrations of the apparatus 100, (iii) reduced instances of dopants being implanted at an incorrect implantation angle as a result of vibration of a semiconductor wafer of the set of semiconductor wafers 108 while the ion beam 114 is being emitted to the semiconductor wafer (while the semiconductor wafer is at the beam position 116, for example), or (iv) improved stability of the ion implantation process.

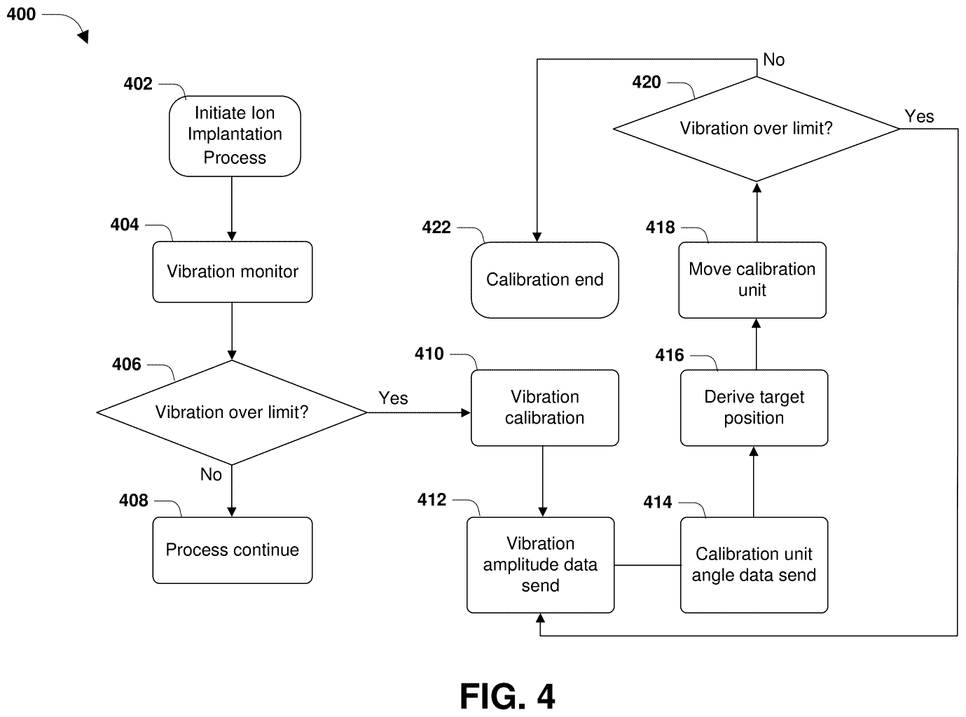

A method 400 is illustrated in FIG. 4 in accordance with some embodiments. In some embodiments, the method 400 includes initiating, at 402, the ion implantation process to introduce dopants to the set of semiconductor wafers 108. In some embodiments, the method 400 includes monitoring (e.g., continuously, discontinuously, and/or periodically monitoring), at 404, one or more vibration metrics. In some embodiments, the method 400 includes comparing, at 406, the one or more vibration metrics and/or updated values of the one or more vibration metrics with the predefined vibration metric threshold. In some embodiments, the method 400 includes continuing, at 408, the ion implantation process (without vibration calibration, for example) in response to the one or more vibration metrics not meeting the predefined vibration metric threshold. In some embodiments, the method 400 includes triggering, at 410, the vibration calibration process in response to determining that a vibration metric associated with the apparatus 100 meets the predefined vibration metric threshold. In some embodiments, at 412, the controller 202 retrieves (via the one or more vibration metric signals 212, for example) one or more vibration metrics (e.g., vibration amplitude data) from the set of vibration measurement devices 104. In some embodiments, at 414, the controller 202 retrieves position information associated with the set of calibration units 106. In some embodiments, the position information is indicative of a current position (e.g., a current angular position relative to the reference position R1) of each calibration unit of one, some, or all of the set of calibration units 106. In some embodiments, at 416, the controller 202 derives a set of target positions (e.g., the first set of target positions AP3 and/or AP4) based upon the one or more vibration metrics and/or the position information. In some embodiments, the method 400 includes moving, at 418, calibration units of the set of calibration units 106 to one or more respective positions of the set of target positions. In some embodiments, the method 400 includes comparing, at 420, one or more vibration metrics and/or updated values of the one or more vibration metrics with the predefined vibration metric threshold. In some embodiments, in response to determining that a vibration metric of the one or more vibration metrics meets (e.g., exceeds) the predefined vibration metric threshold, the controller 202 performs, anew, at least one of act 412, act 414, act 416, act 418, or act 420. In some embodiments, in response to determining that the one or more vibration metrics do not meet the predefined vibration metric threshold at 420, the controller 202 completes the calibration process at 422. In some embodiments, in response to completing the calibration process at 422, the controller 202 monitors (e.g., continuously, discontinuously, and/or periodically monitors) one or more vibration metrics (at 404, for example) and/or compares (at 406, for example) the one or more vibration metrics (and/or updated values of the one or more vibration metrics) with the predefined vibration metric threshold.

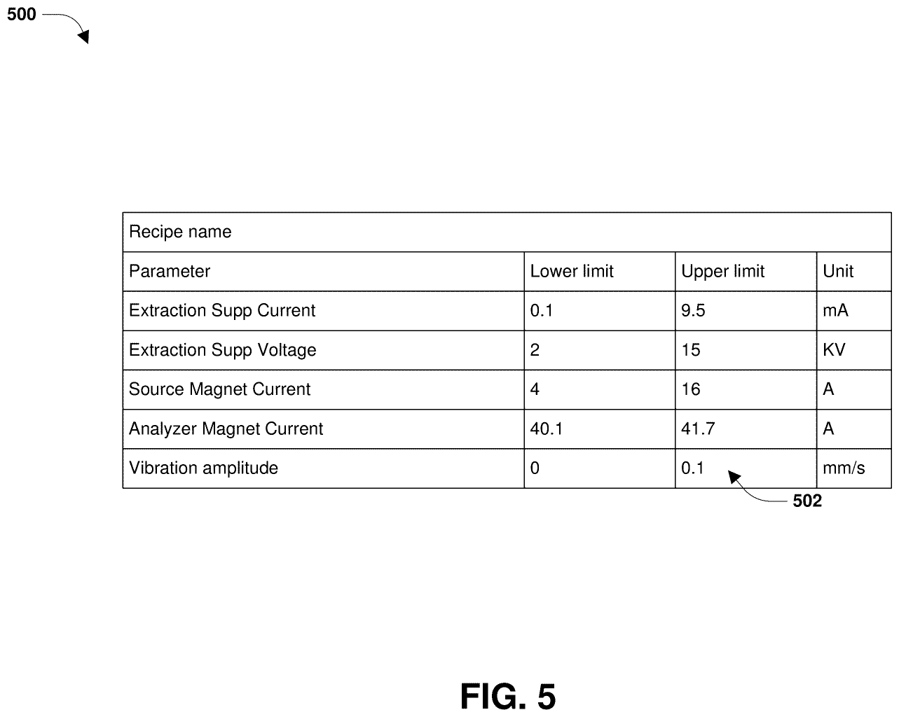

In some embodiments, one or more parameters of the recipe associated with the ion implantation process are indicated by a recipe data structure 500 (shown in FIG. 5). FIG. 5 illustrates the recipe data structure 500 in accordance with some embodiments. In some embodiments, the apparatus 100 receives the recipe data structure 500 and performs the ion implantation process based upon the recipe data structure 500. In some embodiments, the recipe data structure 500 comprises an indication 502 of the predefined vibration metric threshold. In some embodiments, the controller 202 sets the predefined vibration metric threshold to a value (e.g., a maximum vibration amplitude of 0.1 millimeters/second) identified by the indication 502 of the recipe data structure 500. In some embodiments, the recipe data structure 500 is indicative of one or more parameters associated with the ion implantation process. In some embodiments, the one or more parameters comprise at least one of an extraction supply current, an extraction supply voltage, a source magnet current, an analyzer magnet current, etc.

In some embodiments, the apparatus 100 performs one or more acts of the ion implantation process based upon the one or more parameters indicated by the recipe data structure 500. In some embodiments, the one or more acts comprise (i) generating the ion beam 114 according to one or more energy parameters (e.g., at least one of the extraction supply current, the extraction supply voltage, the source magnet current, the analyzer magnet current, etc.) indicated by the recipe data structure 500, (ii) using the wafer support assembly 110 to tilt a semiconductor wafer of the set of semiconductor wafers 108 to a target angle relative to the ion beam 114 to achieve a desired implantation angle of dopants into the semiconductor wafer (e.g., the target angle is identified by the recipe data structure 500), (iii) rotating the disk 103 at a target rotation speed (e.g., the target rotation speed is identified by the recipe data structure 500), or (iv) one or more other acts.

Embodiments are contemplated in which the apparatus 100 is associated with one or more other processes (e.g., semiconductor fabrication processes) in addition to or as an alternative to ion implantation.

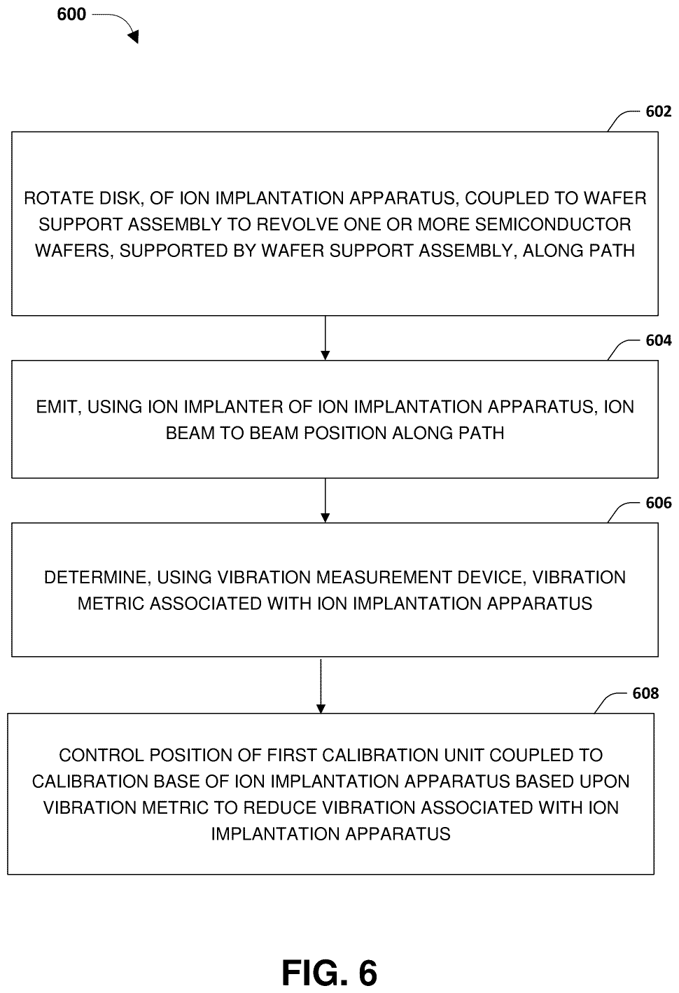

A method 600 is illustrated in FIG. 6 in accordance with some embodiments. In some embodiments, the method 600 includes rotating, at 602, a disk (e.g., the disk 103), of an ion implantation apparatus (e.g., the apparatus 100), coupled to a wafer support assembly (e.g., the wafer support assembly 110) to revolve one or more semiconductor wafers (e.g., the set of semiconductor wafers 108) along a path (e.g., the path 140). In some embodiments, the method 600 includes emitting, at 604, an ion beam (e.g., the ion beam 114) to a beam position (e.g., the beam position 116) along the path using an ion implanter (e.g., the ion implanter 112) of the ion implanter apparatus. In some embodiments, the method 600 includes determining, at 606, a vibration metric associated with the ion implantation apparatus using a vibration measurement device (e.g., the set of vibration measurement devices 104). In some embodiments, the method 600 includes controlling, at 608, a position of a first calibration unit (e.g., the first calibration unit 106a) coupled to calibration base (e.g., the calibration base 105) based upon the vibration metric to reduce a vibration associated with the ion implantation apparatus.

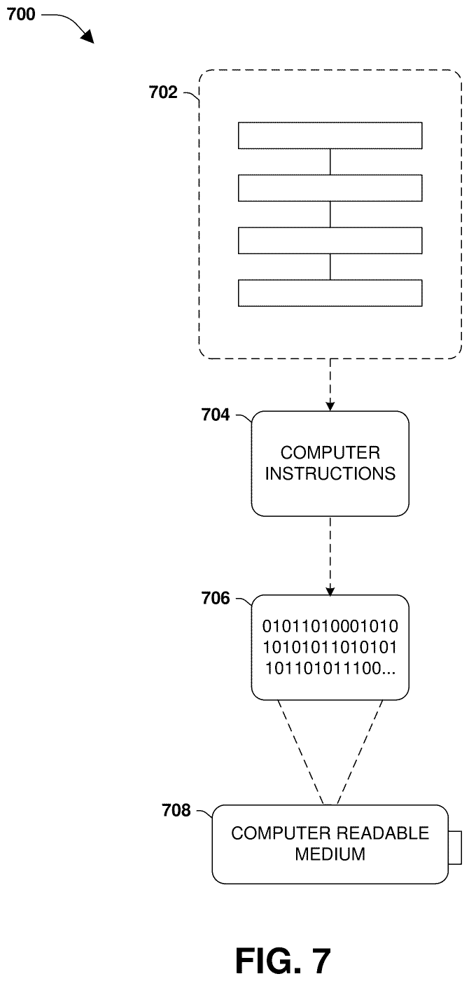

One or more embodiments involve a computer-readable medium comprising processor-executable instructions configured to implement one or more of the techniques presented herein. An exemplary computer-readable medium is illustrated in FIG. 7, wherein the embodiment 700 comprises a computer-readable medium 708 (e.g., a CD-R, DVD-R, flash drive, a platter of a hard disk drive, etc.), on which is encoded computer-readable data 706. This computer-readable data 706 in turn comprises a set of processor-executable computer instructions 704 configured to implement one or more of the principles set forth herein when executed by a processor. In some embodiments 700, the processor-executable computer instructions 704 are configured to implement a method 702, such as at least some of the aforementioned method(s) when executed by a processor. In some embodiments, the processor-executable computer instructions 704 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, an apparatus is provided. The apparatus includes a disk configured to rotate during an ion implantation process. The apparatus includes a wafer support assembly coupled to the disk and configured to support one or more semiconductor wafers. The rotation of the disk causes the one or more semiconductor wafers to revolve along a path. The apparatus includes an ion implanter configured to emit an ion beam to a beam position along the path. The apparatus includes a vibration calibration device including a calibration base coupled to the disk and a first calibration unit coupled to the calibration base. The vibration calibration device is configured to move the first calibration unit from a first position to a second position to reduce a vibration associated with the apparatus.

In some embodiments, a method is provided. The method includes rotating a disk, of an ion implantation apparatus, coupled to a wafer support assembly to revolve one or more semiconductor wafers, supported by the wafer support assembly, along a path. The method includes emitting, using an ion implanter of the ion implantation apparatus, an ion beam to a beam position along the path. The method includes determining, using a vibration measurement device, a vibration metric associated with the ion implantation apparatus. The method includes controlling a position of a first calibration unit coupled to a calibration base of the ion implantation apparatus based upon the vibration metric to reduce a vibration associated with the ion implantation apparatus.

In some embodiments, an apparatus is provided. The apparatus includes a disk configured to rotate during an ion implantation process. The apparatus includes a wafer support assembly coupled to the disk and configured to support one or more semiconductor wafers, wherein the rotation of the disk causes movement of the one or more semiconductor wafers. The apparatus includes an ion implanter configured to introduce dopants to the one or more semiconductor wafers. The apparatus includes a vibration measurement device configured to determine a vibration metric associated with the apparatus. The apparatus includes a vibration calibration device including a calibration base coupled to the disk and a first calibration unit coupled to the calibration base. The vibration calibration device is configured to control a position of the first calibration unit based upon the vibration metric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus, comprising:
a disk configured to rotate during an ion implantation process;
a wafer support assembly coupled to the disk and configured to support one or more semiconductor wafers, wherein the rotation of the disk causes the one or more semiconductor wafers to revolve along a path;
an ion implanter configured to emit an ion beam to a beam position along the path; and
a vibration calibration device comprising:
a calibration base coupled to the disk; and
a first calibration unit coupled to the calibration base,
wherein the vibration calibration device is configured to move the first calibration unit from a first position to a second position to reduce a vibration associated with the apparatus.

2. The apparatus of claim 1, comprising:
a vibration measurement device configured to determine a vibration metric associated with the apparatus, wherein the vibration calibration device is configured to determine the second position based upon the vibration metric.

3. The apparatus of claim 1, comprising:
a vibration measurement device configured to determine a vibration metric associated with the apparatus, wherein the vibration calibration device is configured to move the first calibration unit from the first position to the second position in response to the vibration metric meeting a threshold.

4. The apparatus of claim 1, wherein:
the vibration calibration device comprises a first calibration unit actuator configured to move the first calibration unit from the first position to the second position.

5. The apparatus of claim 1, wherein:
the vibration calibration device comprises a second calibration unit coupled to the calibration base.

6. The apparatus of claim 5, wherein:
the vibration calibration device is configured to move the second calibration unit from a third position to a fourth position to reduce the vibration associated with the apparatus.

7. The apparatus of claim 1, wherein:
the ion beam emitted by the ion implanter introduces dopants to the one or more semiconductor wafers.

8. The apparatus of claim 1, wherein:
the first calibration unit moves along a rail defined in the calibration base from the first position to the second position.

9. A method, comprising:
rotating a disk, of an ion implantation apparatus, coupled to a wafer support assembly to revolve one or more semiconductor wafers, supported by the wafer support assembly, along a path;
emitting, using an ion implanter of the ion implantation apparatus, an ion beam to a beam position along the path;
determining, using a vibration measurement device, a vibration metric associated with the ion implantation apparatus; and
controlling a position of a first calibration unit coupled to a calibration base of the ion implantation apparatus based upon the vibration metric to reduce a vibration associated with the ion implantation apparatus.

10. The method of claim 9, wherein controlling the position of the first calibration unit comprises:
determining a target position of the first calibration unit based upon the vibration metric; and
moving the first calibration unit to the target position.

11. The method of claim 9, wherein controlling the position of the first calibration unit comprises:
comparing the vibration metric with a threshold; and
moving the first calibration unit from a first position to a second position in response to the vibration metric meeting the threshold.

12. The method of claim 9, comprising:
controlling a position of a second calibration unit coupled to the calibration base based upon the vibration metric.

13. The method of claim 12, wherein controlling the position of the first calibration unit and controlling the position of the second calibration unit comprise:
determining a first target position of the first calibration unit based upon the vibration metric;
determining a second target position of the second calibration unit based upon the vibration metric;
moving the first calibration unit to the first target position; and
moving the second calibration unit to the second target position.

14. The method of claim 12, wherein controlling the position of the first calibration unit and controlling the position of the second calibration unit comprise:
comparing the vibration metric with a threshold; and
in response to the vibration metric meeting the threshold, at least one of:
moving the first calibration unit from a first position to a second position; or
moving the second calibration unit from a third position to a fourth position.

15. An apparatus, comprising:
a disk configured to rotate during an ion implantation process;
a wafer support assembly coupled to the disk and configured to support one or more semiconductor wafers, wherein the rotation of the disk causes movement of the one or more semiconductor wafers;
an ion implanter configured to introduce dopants to the one or more semiconductor wafers;
a vibration measurement device configured to determine a vibration metric associated with the apparatus; and
a vibration calibration device comprising:
a calibration base coupled to the disk; and
a first calibration unit coupled to the calibration base,
wherein the vibration calibration device is configured to control a position of the first calibration unit based upon the vibration metric.

16. The apparatus of claim 15, wherein:
the vibration calibration device is configured to:
determine a target position of the first calibration unit based upon the vibration metric; and
move the first calibration unit to the target position.

17. The apparatus of claim 15, wherein:
the vibration calibration device is configured to:
compare the vibration metric with a threshold; and
move the first calibration unit from a first position to a second position in response to the vibration metric meeting the threshold.

18. The apparatus of claim 15, wherein:
the vibration calibration device comprises a first calibration unit actuator configured to move the first calibration unit from a first position to a second position based upon the vibration metric.

19. The apparatus of claim 15, wherein:
the vibration calibration device comprises a second calibration unit coupled to the calibration base.

20. The apparatus of claim 19, wherein:
the vibration calibration device is configured to:
compare the vibration metric with a threshold; and
in response to the vibration metric meeting the threshold, at least one of:
move the first calibration unit from a first position to a second position; and
move the second calibration unit from a third position to a fourth position.
